(19) United States
(12) Patent Application Publication
(10) Pub. No.: US 2001/0029436 A1
(43) Pub. Date: Oct. 11, 2001

(54) Semiconductor electrical characteristics evaluation apparatus and semiconductor electrical characteristics evaluation method

(75) Inventor: Ryoichi Fukasawa, Yuzukami-Mura (JP)

Correspondence Address: OLIFF & BERRIDGE, PLC, 277 S. WASHINGTON STREET, SUITE 500, ALEXANDRIA, VA, 22314, US

(73) Assignee: TOCHIGI NIKON CORPORATION, NIKON CORPORATION

(21) Appl. No.: 09/816,085

(22) Filed: Mar. 26, 2001

(30) Foreign Application Priority Data
Mar. 27, 2000 (JP) 2000-085982
Jul. 19, 2000 (JP) 2000-218673
Sep. 18, 2000 (JP) 2000-282497

(51) Int. Cl. G06F 19/00; G01R 27/28; G01R 31/00; G01R 31/14

(52) U.S. Cl. 702/117

(57) ABSTRACT

An electrical characteristics evaluation apparatus comprises a terahertz pulse light source that irradiates terahertz pulse light onto a semiconductor material, a light detector that detects pulse light having been transmitted through or having been reflected by the semiconductor material, a measurement device that obtains a spectral transmittance or a spectral reflectance by using a time-series waveform of the electric field intensity of the transmitted pulse light or the reflected pulse light and an arithmetic operation unit that calculates an electrical characteristics parameter of the semiconductor material based upon the spectral transmittance or the spectral reflectance. By adopting this electrical characteristics evaluation apparatus and the corresponding electrical characteristics evaluation method, the electrical material quantities (such as the carrier density, the mobility, the resistivity and the electrical conductivity) of the measurement target, i.e.,the semiconductor material, can be measured and inspected without contaminating or damaging the semiconductor material.

### INCORPORATION BY REFERENCE

The disclosures of the following priority applications are herein incorporated by reference:

Japanese Patent Application No. 2000-85982 filed Mar. 27, 2000

Japanese Patent Application No. 2000-218673 filed Jul. 19, 2000

Japanese Patent Application No. 2000-282497 filed Sep. 18, 2000

### BACKGROUND OF THE INVENTION

1. Field of the Invention

The present invention relates to an electrical characteristics evaluation apparatus and an electrical characteristics evaluation method that allow electrical characteristics such as the carrier density, the mobility, the resistivity and the electrical conductivity of a semiconductor material which may be a semiconductor wafer, an ingot, an epitaxial grown film or the like to be measured in a non-destructive, non-contact method and the electrical characteristics to be rendered into images.

2. Description of the Related Art

In the semiconductor device industry, the material quantities including the carrier density, the mobility, the resistivity and the electrical conductivity which represent the electrical characteristics of a semiconductor material used to manufacture a device are crucial factors that determine the performance of the semiconductor device. Such material quantities are conventionally measured through electric measurement methods such as the four-point probe.

In such an electric measurement method in the prior art, the semiconductor material is often machined to facilitate the measurement or the semiconductor material is placed in electrical contact with a measurement terminal of the measuring instrument for measurement. Thus, the semiconductor material having undergone the measurement can no longer be used or it may cause contamination or a defect. In addition, while the average of material quantities measured at individual measurement terminals is obtained through electric measurement in the prior art, it takes a great deal of time to measure the spatial distribution of a material quantity over the entire material, thereby presenting difficulty in capturing as an image the information with regard to the spatial distribution (in particular, inconsistency) of the material quantity.

### SUMMARY OF THE INVENTION

An object of the present invention is to provide an electrical characteristics evaluation apparatus and an electrical characteristics evaluation method that allow electrical material quantities of a measurement target to be measured and tested without contaminating or otherwise causing a defect in the measurement target.

The semiconductor electrical characteristics evaluation apparatus according to the present invention comprises a terahertz pulse light source that irradiates terahertz pulse light onto a semiconductor material, a light detector that detects transmitted pulse light having been transmitted through the semiconductor material or reflected pulse light having been reflected by the semiconductor material, a measurement device that obtains a spectral transmittance or a spectral reflectance based upon a time-series waveform of the electric field intensity of the transmitted pulse light or the reflected pulse light and an arithmetic operation unit that calculates an electrical characteristics parameter of the semiconductor material in conformance to the spectral transmittance or the spectral reflectance.

The arithmetic operation unit may execute an analysis based upon Drude's light-absorption theory or execute an analysis based upon the dielectric function theory.

The semiconductor electrical characteristics evaluation apparatus according to the present invention may further comprise an image processing device that renders the electrical characteristics parameter into a two-dimensional image as a spatial distribution.

The semiconductor electrical characteristics evaluation apparatus according to the present invention may be further provided with a condenser optical system that condenses terahertz pulse light and guides a condensed light flux to the semiconductor material and a mechanical scanning system that causes the condensed light flux and the semiconductor material to move relative to each other on the surface of the semiconductor material.

Instead of adopting the scanning method described above, the semiconductor electrical characteristics evaluation apparatus according to the present invention may be provided with an expander optical system that expands the diameter of the terahertz pulse beam and guides an expanded light flux at once onto the entire surface of the semiconductor material. In this case, the light detector is constituted of a two-dimensional light detector that two-dimensionally detects transmitted pulse light or reflected pulse light having been transmitted through or reflected by the semiconductor material irradiated with the expanded light flux.

The semiconductor electrical characteristics evaluation apparatus according to the present invention may be further provided with a tilt mechanism that tilts the light flux (a condensed light flux or an expanded light flux) guided to the semiconductor material and the semiconductor material relative to each other and a computer graphics device that synthesizes a three-dimensional sectioned image by using a plurality of two-dimensional images obtained at varying tilt angles.

In the method of semiconductor electrical characteristics evaluation achieved by scanning terahertz pulse light onto a semiconductor material, a condensed light flux of the terahertz pulse light is irradiated onto the semiconductor material, the condensed light flux and the semiconductor material are caused to move relative to each other within the surface of the semiconductor material, transmitted pulse light or reflected pulse light at various points of the semiconductor material is sequentially detected, a spectral transmittance or a spectral reflectance is calculated based upon a time-series waveform of the electric field intensity of the transmitted pulse light or the reflected pulse light and an electrical characteristics parameter of the semiconductor material is calculated in conformance to the spectral transmittance or the spectral reflectance.

In the method of semiconductor electrical characteristics evaluation according to the present invention achieved by irradiating at once terahertz pulse light onto a semiconductor material, an expanded light flux achieved by expanding the diameter of the terahertz pulse light is irradiated at once over the entire surface of the semiconductor material, transmitted pulse light or reflected pulse light having been transmitted through or reflected by the semiconductor material irradiated with the expanded light flux is detected at once, and a spectral transmittance or a spectral reflectance is calculated and then an electrical characteristics parameter of the semiconductor material is calculated as in the method described above.

In a semiconductor electrical characteristics evaluation method adopting either of the scanning system or the batch condensing method described above, the spectral transmittance or the spectral reflectance may be calculated based upon a time-series waveform of the electric field intensity measured by inserting the semiconductor material in the optical path in which the transmitted pulse light or the reflected pulse light is detected and a time-series waveform of the electric field intensity measured without inserting the semiconductor material in the detection optical path.

### BRIEF DESCRIPTION OF THE DRAWINGS

FIG. 1 is a schematic diagram illustrating the scanning-type imaging photometric method adopted in the electrical characteristics evaluation apparatus in an embodiment;

FIG. 2A is a block diagram illustrating the principle of the time-series waveform measurement and FIG. 2B is a graph presenting an example of a time-series waveform;

FIG. 3 is an overall block diagram of the electrical characteristics evaluation apparatus adopting the scanning-type imaging photometric method;

FIG. 4A shows time-series transmitted images obtained by the electrical characteristics evaluation apparatus in the embodiment and FIG. 4B shows the spectral characteristics;

FIGS. 5A and 5B illustrate the principle of the method of analysis adopted in the electrical characteristics evaluation apparatus in the embodiment;

FIG. 6 presents a process diagram of the method of analysis (the method based upon Drude's light absorption theory) adopted in the electrical characteristics evaluation apparatus in the embodiment;

FIG. 7 is a conceptual diagram illustrating the process of obtaining a three-dimensional sectioned image;

FIG. 8 presents an overall view of the electrical characteristics evaluation apparatus adopting the scanning-type imaging photometric method, showing the individual components constituting the apparatus;

FIG. 9 shows a time-series waveform of the electric field intensity obtained by the electrical characteristics evaluation apparatus in the embodiment;

FIG. 10 presents a graph of the frequency dependency manifested by the electric field amplitude observed in the electrical characteristics evaluation apparatus in the embodiment;

FIG. 11A shows an image of an electrical characteristic of a semiconductor obtained by using visible light and FIG. 11B presents an image of the electrical characteristic of the semiconductor obtained by using terahertz light;

FIG. 12 is a schematic diagram provided to illustrate a non-scanning-type imaging photometric method;

FIG. 13 is an overall block diagram of the electrical characteristics evaluation apparatus in an embodiment that adopts the non-scanning-type imaging photometric method;

FIG. 14 illustrates another structure that may be assumed by the electrical characteristics evaluation apparatus adopting the scanning-type imaging photometric method;

FIG. 15 is a process diagram of another analysis method (a method based upon the dielectric function theory) that may be adopted at the electrical characteristics evaluation apparatus; and

FIG. 16 illustrates another structure that may be assumed by the electrical characteristics evaluation apparatus adopting the non-scanning-type photometric method.

### DETAILED DESCRIPTION OF THE PREFERRED EMBODIMENTS

The following is a detailed explanation of the embodiments of the present invention, given in reference to the drawings.

The electrical characteristics evaluation apparatus according to the present invention irradiates pulse light (terahertz pulse light) in the terahertz frequency range onto a semiconductor material, detects pulse light having been transmitted through or reflected by the semiconductor material, calculates a spectral transmittance or a spectral reflectance (spectral characteristics) based upon the results of various detections and measures and evaluates an electrical characteristics parameter of the semiconductor material.

A spatial image representing a material quantity related to electrical characteristics of the semiconductor material may be reproduced at a resolution corresponding to the light wavelength order, based upon a two-dimensional distribution (an electric field intensity distribution) of the transmitted pulse light or the reflected pulse light, i.e., based upon transmitted images or reflected images. In more specific terms, the distribution of the electrical characteristics parameter of the semiconductor material may be measured to test the electrical characteristics of the semiconductor material by measuring a change occurring over time in the transmitted images or the reflected images, performing a Fourier transform on the results of the measurement to obtain a two-dimensional projected image (a spectral image) at each frequency setting and analyzing the spectral images.

Now, the method of analysis is explained in reference to an example in which the analysis is performed based upon Drude's light absorption theory to be detailed later. It is desirable that the terahertz pulse light used in the electrical characteristics evaluation apparatus according to the present invention be in a frequency range of 0.1×10¹² Hz˜80×10¹² Hz.

The photometric optical system employed to obtain transmitted images or reflected images of a semiconductor material by using terahertz pulse light may be either a scanning-type imaging optical system or a non-scanning-type imaging optical system.

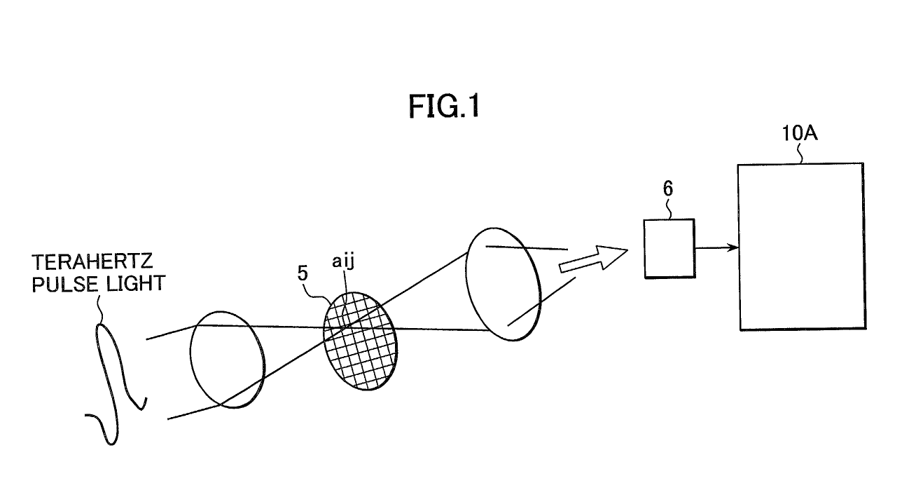

FIG. 1 is a schematic diagram provided to illustrate the scanning-type imaging photometric method achieved by irradiating terahertz pulse light condensed at one point of the semiconductor material. The following is an explanation given on an example in which transmitted images are obtained.

A condensed light flux (terahertz pulse light) irradiated from a terahertz pulse light source (not shown) onto a semiconductor material 5 is transmitted through one point (a pixel aij) of the semiconductor material 5 and reaches a terahertz pulse detector 6. The terahertz pulse detector 6 is provided with a light-receiving surface corresponding to a single pixel. The transmitted pulse light having been transmitted through the one point (the pixel aij) of the semiconductor material 5 is light effected in conformance to the electrical characteristics of the semiconductor material 5. The pulse width of the transmitted pulse light is normally larger than the pulse width of the terahertz pulse light irradiated on the semiconductor material 5.

The terahertz pulse detector 6 receives the transmitted pulse light having been transmitted through the semiconductor material 5 and outputs a signal which is in proportion to the electric field intensity E(i, j) of the transmitted pulse light to a computer 10A (to be described later).

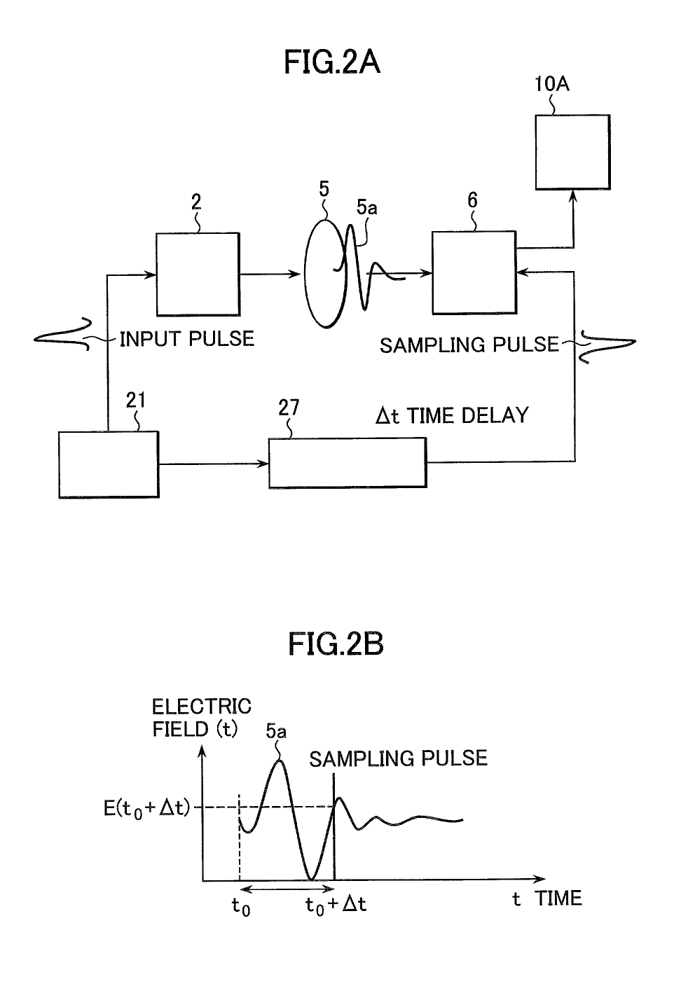

Next, the method of measuring the time-series waveform of the electric field intensity at the computer 10A is explained. FIG. 2A is a block diagram provided to illustrate the principle of the time-series waveform measurement and FIG. 2B is a graph presenting an example of a time-series waveform.

At a time point t0, pulse light (terahertz pulse light) is emitted from a terahertz pulse light source 2 in response to an input pulse, and transmitted pulse light 5a having been transmitted through the semiconductor material 5 reaches the terahertz pulse detector 6. The input pulse refers to a pulse input from a laser 21 to the terahertz pulse light source 2 in order to generate the terahertz pulse light (to be detailed later).

The input pulse is transmitted to the terahertz pulse detector 6 via a time delay device 27 as a sampling pulse to be used to measure the time-series waveform of the electric field intensity of the transmitted pulse light 5a. The terahertz pulse detector 6 detects the electric field intensity of the transmitted pulse light 5a at the point in time at which the sampling pulse is received and outputs the electric field intensity thus detected to the computer 10A.

When the timing with which the sampling pulse is transmitted is delayed by Δt at the time delay device 27, the terahertz pulse detector 6 detects the electric field intensity E(t0+Δt) of the transmitted pulse light 5a at a time point t0+Δt (see FIG. 2B).

By changing the time delay Δt at the time delay device 27, the electric field intensity E(t) at any time point t can be ascertained and, thus, a time-series waveform of the electric field intensity of the transmitted pulse light 5a is obtained.

Next, the main components constituting the electrical characteristics evaluation apparatus in an embodiment of the present invention are explained.

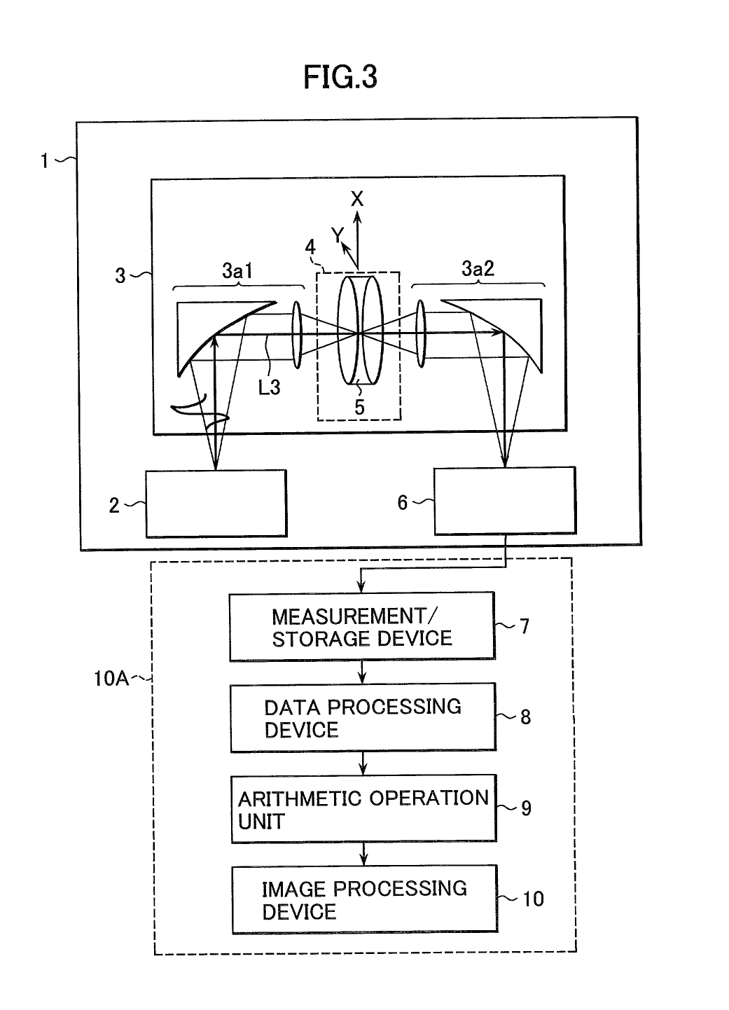

FIG. 3 is a schematic block diagram of the electrical characteristics evaluation apparatus according to the present invention adopting the scanning-type imaging method. In a measurement chamber 1, the terahertz pulse light source 2, a test piece chamber 3 and the terahertz pulse detector 6 are provided. The terahertz pulse detector 6 in the measurement chamber 1 is connected to the computer 10A which is provided outside the measurement chamber 1. In FIG. 3., the laser 21 and the time delay device 27 explained in reference to FIG. 2A are not shown.

The test piece chamber 3 houses therein photometric optical systems 3a1 and 3a2 (the following explanation is given by referring to them generically as 3a) each provided to perform photometry at one point on the semiconductor material 5 and a mechanical scanning system 4 (e.g., an X-Y stage) that causes the semiconductor material 5 to move on a two-dimensional plane. These members are engaged in a scanning operation to obtain two-dimensional projected images of the semiconductor material 5 in the terahertz frequency range.

The semiconductor material 5 is supported by the mechanical scanning system 4. By employing the mechanical scanning system 4 to scan the semiconductor material 5 along the X-Y plane extending almost perpendicular to an optical axis L3 of a condensed light flux, transmitted pulse light having been transmitted through various points of the semiconductor material 5 can be sequentially received at the terahertz pulse detector 6. The results thus obtained are transmitted to the computer 10A where a two-dimensional distribution (transmitted image) of the electric field intensity is obtained by spatially synthesizing the electric field intensity levels at the individual points of the semiconductor material 5.

The computer 10A comprises a measurement/storage device 7, a data processing device 8, an arithmetic operation unit 9 and an image processing device 10.

The measurement/storage device 7 measures and stores in memory a time-series signal indicating the electric field intensity output from the terahertz pulse detector 6 in correspondence to each pixel. The data processing device 8 performs an arithmetic operation to convert the time-series signals indicating the electric field intensity levels to a frequency spectrum through a Fourier transform implemented in units of individual pixels, to obtain a spectral transmittance.

The arithmetic operation unit 9 calculates electrical characteristics parameters (the carrier density, the mobility, the resistivity and the electrical conductivity) of the semiconductor material 5 by using Drude's light absorption theory based upon the frequency dependency of the spectral transmittance ascertained by the data processing device 8.

The image processing device 10 restructures numerical value data corresponding to the individual pixels calculated by the arithmetic operation unit 9 on the computer and renders the restructured data into a two-dimensional image. In addition, the image processing device 10 engages in a linear conversion operation to synthesize a three-dimensional sectioned image from a plurality of two-dimensional projected images.

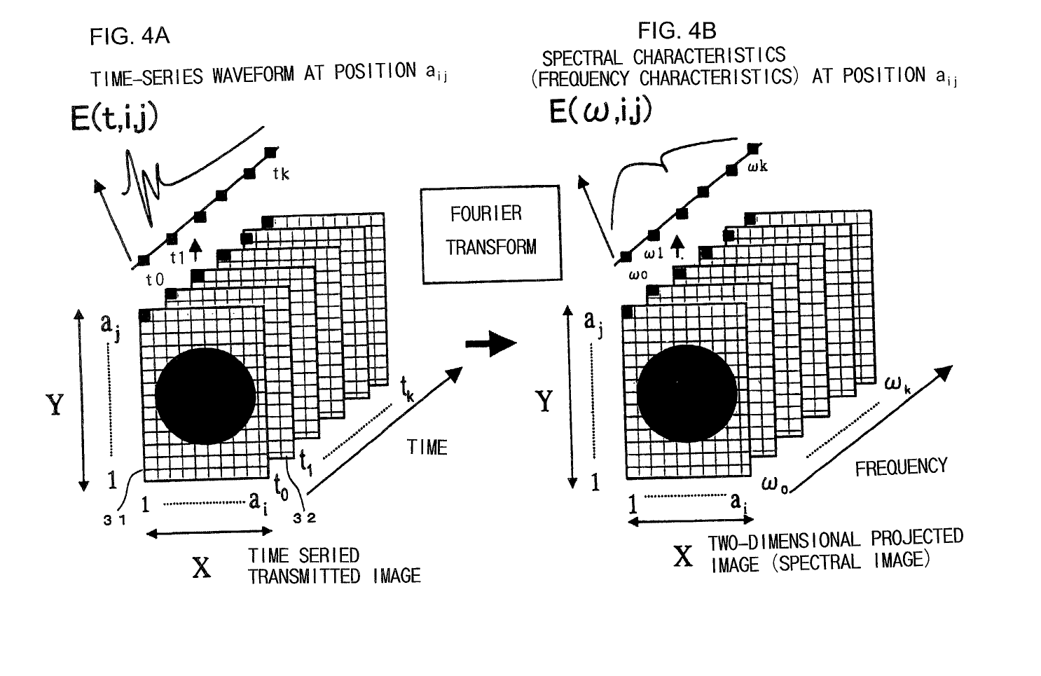

FIG. 4 is a conceptual diagram provided to illustrate the principle based upon which spectral characteristics B are ascertained based upon time-series transmitted images A. By setting Δt to 0 relative to the time point t0 at the time delay device 27 (see FIG. 2A) and measuring electric field intensity levels in correspondence to all the pixels (i.e., for i×j pixels) through X-Y scanning of the semiconductor material 5, an electric field intensity distribution (transmitted image) 31 of the transmitted pulse light within the X-Y plane at the time point t0 is obtained. By setting Δt so as to satisfy t0+Δt=t1 at the time delay device 27 and measuring electric field intensity levels in a similar manner, a transmitted image 32 at the time point t1 is obtained. By changing the time delay Δt in this manner, transmitted images 31, 32, . . . at various time points (t0˜tk) are measured.

By extracting the numerical value data corresponding to the time-series transmitted images 31, 32 . . . thus obtained along the time axis with regard to a given pixel (aij), a time-series waveform E(t, i, j) of the electric field intensity spanning the period of time extending from the time point t0 to the time point tk is obtained, as shown in FIG. 4A. Since similar time series waveforms of the electric field intensity can be obtained with regard to other pixels as well, the change occurring in the electric field intensity distribution of the transmitted pulse light within the X-Y plane over time can be viewed as if looking at a dynamic image, by utilizing the time delay device 27.

Through the procedure described above, the time-series waveform E (t, i, j) of the electric field intensity is obtained for each pixel (aij) at the measurement/storage device 7. At the data processing device 8, the time-series waveforms E (t, i, j) stored at the measurement/storage device 7 undergo a Fourier transform operation in units of the individual pixels (aij). As a result, spectral characteristics E (ω, i, j) at each pixel (aij) of the semiconductor material 5 are obtained, as shown in FIG. 4B. By reconstructing these numerical value data at the image processing device 10, an image of the electric field intensity within the X-Y plane over the frequency range of ω0˜ωk, i.e., a two-dimensional projected image (spectral image) is obtained.

Information representing the electrical characteristics of the semiconductor material 5 is included in the series of two dimensional projected images. By analyzing such information at the arithmetic operation unit 9 based upon Drude's light absorption theory which is to be detailed later, the images are converted to two-dimensional projected image information related to material quantities representing the electrical characteristics of the semiconductor material.

It is to be noted that instead of performing X-Y scanning of the semiconductor material 5, a photometric optical system, i.e., the optical system 3a2 that irradiates terahertz pulse light onto the semiconductor material 5 and also guides transmitted pulse light having been transmitted through the semiconductor material 5 to the terahertz pulse detector 6, may be engaged in an interlocking operation to obtain similar transmitted images 31, 32 . . . .

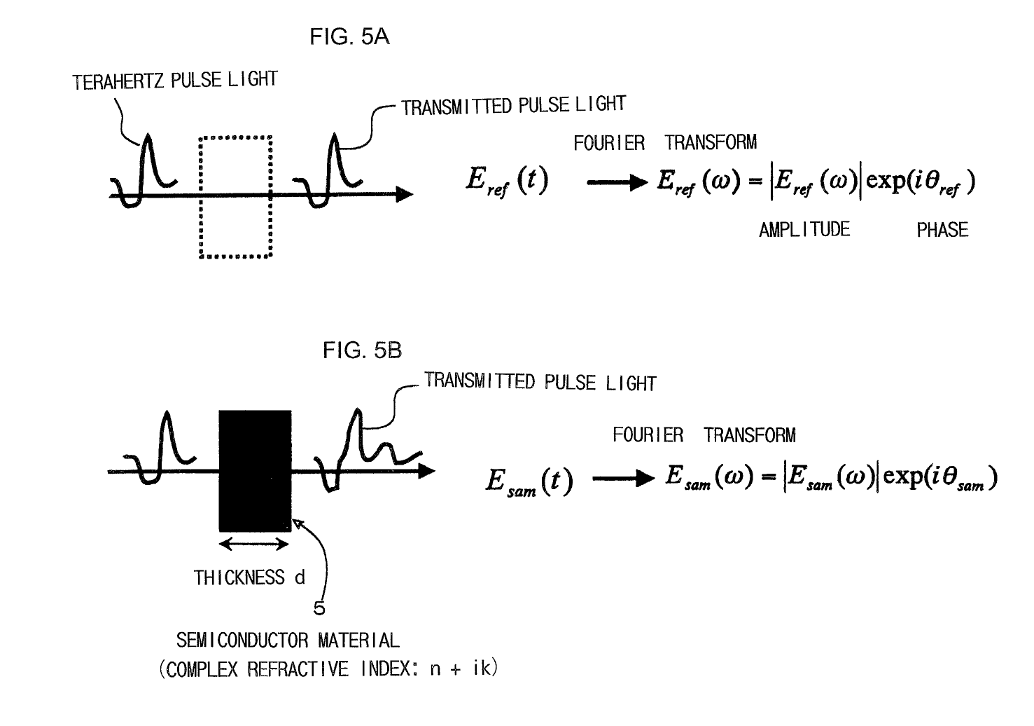

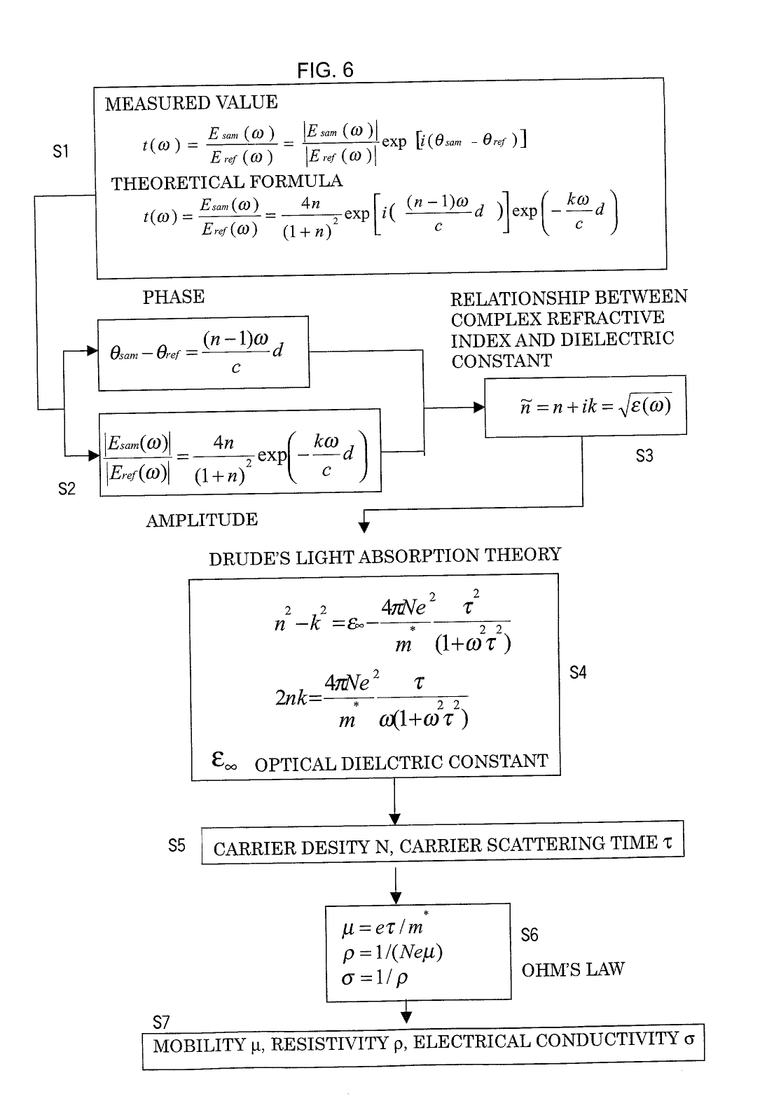

An explanation is given in reference to FIGS. 5A, 5B and 6 on a method of analysis that may be adopted to calculate the carrier density, the mobility, the resistivity and the electrical conductivity of the semiconductor material 5 by employing the apparatus described above. FIGS. 5A and 5B illustrate a process implemented during the analysis at the electrical characteristics evaluation apparatus according to the present invention. FIG. 6 is a process diagram of the procedure taken to implement the analysis to calculate electrical material values (the carrier density, the mobility, resistivity, the electrical conductivity and the like) of the semiconductor material 5. This analysis procedure is implemented based upon Drude's light absorption theory. To simplify the explanation, the analysis performed on a single pixel is described below.

Terahertz pulse light is irradiated on one point (equivalent to one pixel in FIG. 4) of the semiconductor material 5 and a time-series waveform E(t) of the electric field intensity of the terahertz pulse light having been transmitted through the semiconductor material 5 (transmitted pulse light) is recorded at the measurement/storage device 7. By performing a Fourier transform on the time-series waveform E(t) of the electric field intensity thus obtained at the data processing device 8, the amplitude |E(ω)| and the phase θ of the light are calculated.

The relationship among the time-series waveform E(t), the light amplitude |E(ω)| and the light phase θis defined through the Fourier transform presented in the following formula (1).

$$E ( ω ) = {\int }_{- ∞}^{∞} E ( t ) exp ( - i ω t ) ⅆ t = \vert E ( ω ) \vert exp ( i θ ) \qquad ( 1 )$$

When performing a measurement operation, first, a time-series waveform Eref(t) of the electric field intensity is measured at the measurement/storage device 7 without inserting the semiconductor material 5 (measurement target) in the optical path of the photometric optical system 3a as shown in FIG. 5A. The time-series waveform of the electric field intensity thus measured then undergoes a Fourier transform at the data processing device 8 and, as a result, a reference amplitude |Eref(ω)| and a reference phase θref are obtained.

Next, as shown in FIG. 5B, a time-series waveform Esam(t) of the electric field intensity is measured at the measurement/storage device 7 with the semiconductor material 5 inserted in the optical path of the photometric optical system 3a, and by performing a Fourier transform on the time-series waveform Esam(t) at the data processing device 8, an amplitude |Esam(ω)| and a phase θsam manifested when the measurement target is inserted are ascertained.

The following is a detailed explanation on an example in which an analysis is performed by using transmitted pulse light or a transmitted image having been transmitted through the semiconductor material 5.

The complex amplitude transmittance t(ω) of the semiconductor material 5 is defined as expressed in the following formula (2). Esam(ω) and Eref(ω) respectively represent the Fourier components of the electric field intensity of the light obtained by inserting (see FIG. 5B) and without inserting (see FIG. 5A) the semiconductor material 5 in the optical path of the photometric optical system 3a, which are actually measured. The complex amplitude transmittance t(ω) in formula (2), which is expressed as a ratio of Esam(ω) and Eref(ω), is also a quantity obtained through actual measurement (FIG. 6 S1).

$$t ( ω ) = \frac{{E}_{sam} ( ω )}{{E}_{ref} ( ω )} = \frac{\vert {E}_{sam} ( ω ) \vert}{\vert {E}_{ref} ( ω ) \vert} exp [ i ( {θ}_{sam} - {θ}_{ref} ) ] \qquad ( 2 )$$

With n+ik representing the complex refractive index of the semiconductor material 5, the theoretical complex amplitude transmittance t(ω) manifesting when the semiconductor material 5 having a thickness d is inserted in the optical path (see FIG. 5B) is calculated through the following formula (3) (FIG. 6 S1). It is to be noted that c represents light speed.

$$t ( ω ) = \frac{{E}_{sam} ( ω )}{{E}_{ref} ( ω )} = \frac{4 n}{{( 1 + n )}^{2}} exp [ i ( \frac{( n - 1 ) ω}{c} d ) ] exp ( - \frac{k ω}{c} d ) \qquad ( 3 )$$

By comparing formulae (2) and (3) above, the following formulae (4) and (5) are obtained. Since the left-hand side members of formulae (4) and (5) are each constituted of a measured quantity, the value of n can be calculated through formula (4) as long as the thickness d of the semiconductor material 5 is known. Using the calculated the value of n, the value of k can be calculated through formula (5). Namely, the complex refractive index of n+ik of the semiconductor material 5 can be ascertained (FIG. 6 S2).

$$\begin{matrix}{θ}_{sam} - {θ}_{ref} = \frac{( n - 1 ) ω}{c} d & ( 4 ) \\ \frac{\vert {E}_{sam} ( ω ) \vert}{\vert {E}_{ref} ( ω ) \vert} = \frac{4 n}{{( 1 + n )}^{2}} exp ( - \frac{k ω}{c} d ) & ( 5 )\end{matrix}$$

The measurement/storage device 7 and the data processing device 8 are capable of directly measuring information related to the amplitude and the phase of light without having to measure the intensity of the light (i.e., the square of the electric field) as in the conventional light measurement (see B. B. Hu and M. C. Nuss, OPTICS LETTERS Vol. 20, No. 16, p1716, 1995). For this reason, the complex refractive index n+ik of the semiconductor material 5 can be calculated without engaging in a complicated calculation performed by using Kramers-Kronig relational formula (see “Basics of Optical Material Characteristics” by Keiei Kudo, published by Ohm Publishing House).

The standard relationship between the complex refractive index n+ik and the complex dielectric constant ε(ω) of the semiconductor material 5 is expressed as in the following a formula (6) (FIG. 6 S3).

ñ=n+ik=\sqrt{ε(ω)} (6)

The complex dielectric constant ε(ω) manifesting when forming carriers by adding an impurity to the semiconductor material 5, as deduced through Drude's light absorption theory, is expressed as in the following formula (7).

$$ϵ ( ω ) = {ϵ}_{∞} - \frac{4 π {Ne}^{2}}{{m}^{*}} \frac{1}{ω ( ω + i / τ )} \qquad ( 7 )$$

In formula (7), the optical dielectric constant ε_{∞} and the effective mass m* of the carriers are material constants, and their values vary depending upon the type of the elemental semiconductor (Si, Ge) or the compound semiconductor being evaluated.

Based upon of the relationship between the formulae (6) and (7) above, the following formulae (8) and (9) are obtained (FIG. 6 S4).

$$\begin{matrix}{n}^{2} - {k}^{2} = {ϵ}_{∞} - \frac{4 π {Ne}^{2}}{{m}^{*}} \frac{{τ}^{2}}{( 1 + {ω}^{2} {τ}^{2} )} & ( 8 ) \\ 2 nk = \frac{4 π {Ne}^{2}}{{m}^{*}} \frac{τ}{ω ( 1 + {ω}^{2} {τ}^{2} )} & ( 9 )\end{matrix}$$

(with N representing the carrier density at the semiconductor material 5 and τ representing the carrier scattering time)

The complex refractive index n+ik of the semiconductor material 5 can be measured by the measurement/storage device 7 and the data processing device 8 (FIG. 6 S2), and thus, unknowns in formulae (8) and (9) are the carrier density N and the carrier scattering time τ

By modifying formulae (8) and (9) the carrier scattering time τ is expressed in the following formula (10)

$$τ = \frac{{ϵ}_{∞} - {n}^{2} + {k}^{2}}{2 nk ω} \qquad ( 10 )$$

As a result, the value of the carrier scattering time τ can be determined at the arithmetic operation unit 9 through formula (10), and by incorporating the value of τ thus calculated in formula (9), the value of the carrier density N can be ascertained (FIG. 6 S5).

In addition, the mobility μ, the resistivity ρ and the electrical conductivity σ can be calculated (S7) by incorporating the values of the carrier density N and the carrier scattering time τ that have been calculated into Ohm's Law (the following formulae (11)˜(13) at the arithmetic operation unit 9 (FIG. 6 S6).

μ=eτ/m (11)

ρ=1/(Neμ) (12)

σ=1/ρ (13)

By creating a monochrome chiaroscuro image or a color image on the image processing device 10 based upon the numerical value data obtained through the procedure described above, a two-dimensional projected image representing electrical characteristics parameters (the carrier density N, the mobility μ, the resistivity ρ and the electrical conductivity σ) of the semiconductor is obtained. The acquisition of such a two-dimensional image makes it possible to reduce the length of time required for measurement and evaluation.

Furthermore, a three-dimensional sectioned image with regard to the electrical characteristics parameters (the carrier density N, the mobility μ, the resistivity ρ and the electrical conductivity σ) of the semiconductor material 5 can be obtained at the image processing device 10 as well. Namely, by obtaining a plurality of two-dimensional projected images at varying angle settings at which the semiconductor material 5 is irradiated with terahertz pulse light and performing a linear conversion operation a typical example of which is Radon conversion, a three-dimensional sectioned image is obtained. The method adopted in this process is now explained in detail.

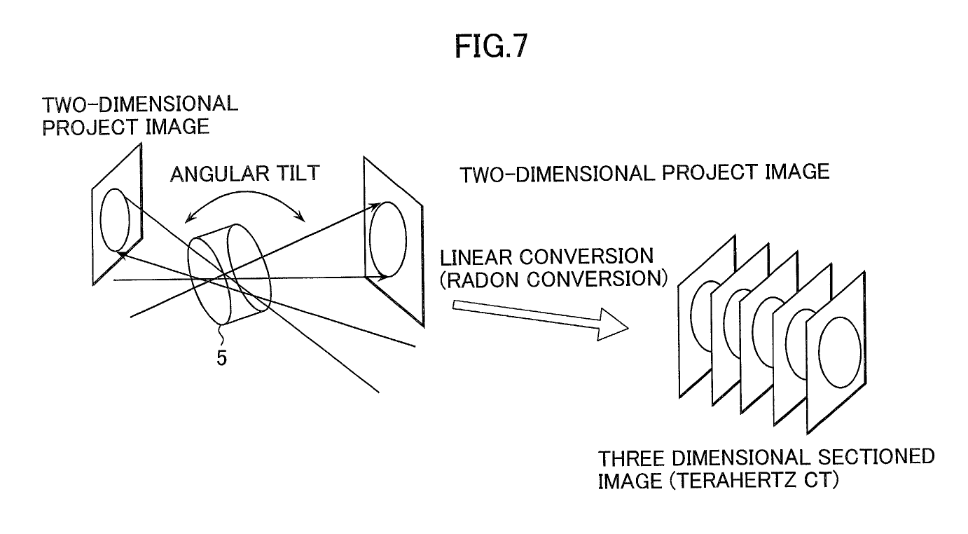

FIG. 7 is a conceptual diagram illustrating the process through which a three-dimensional sectioned image is obtained from two-dimensional projected images. The angle at which the semiconductor material 5 is irradiated with the terahertz pulse light may be changed by providing a tilt mechanism as an integrated part of the X-Y stage 4 or by providing a separate tilt mechanism. The computer 10A is engaged in a linear conversion operation such as Radon conversion by using two-dimensional projected images obtained at varying tilt angles to obtain a three-dimensional sectioned image. This process may be considered to be terahertz CT (computerized tomography).

The Radon conversion refers to a method through which one-dimensional projection data are measured and a two-dimensional section of the original object is restructured from the measured data or two-dimensional projection data are measured and a three-dimensional distribution in the original object is restructured based upon the measured data (see “Image Data Processing” compiled by Sou Kawada and Shigeo Minami, published by CQ Publishing Company).

The following is an explanation of a specific example in which the electrical characteristics evaluation apparatus according to the present invention is utilized to obtain two-dimensional projected images representing the electrical characteristics parameters of a semiconductor.

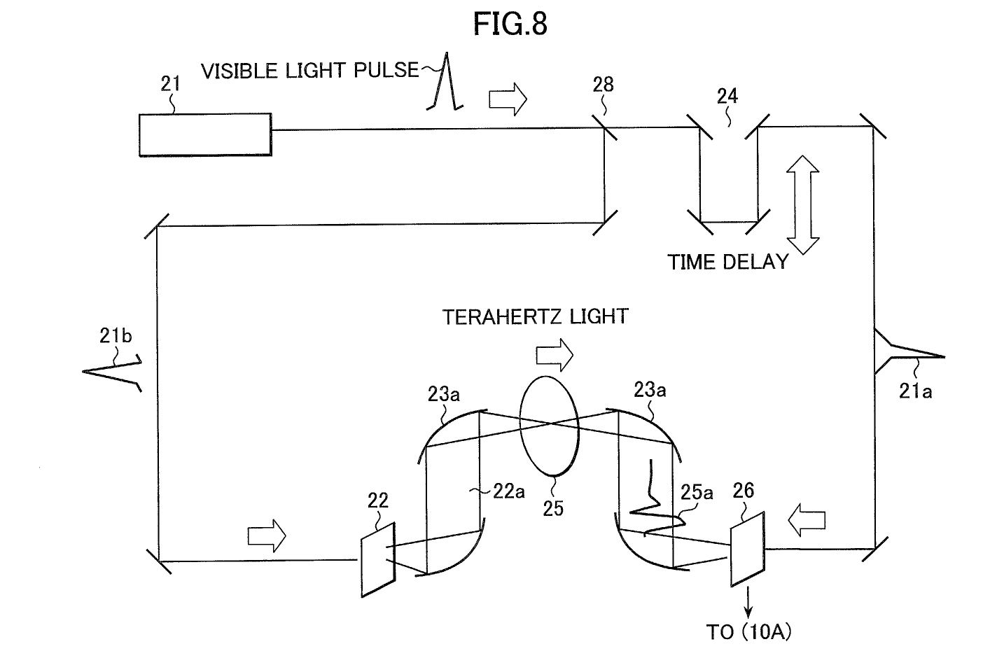

FIG. 8 illustrates the components of the electrical characteristics evaluation apparatus in an embodiment of the present invention which adopts the scanning-type imaging method.

A visible light pulse emitted from a femto-second visible light pulse laser 21 is branched to advance along two directions by a beam splitter 28 so that the light advancing along one direction irradiates a terahertz pulse light source 22 and the light advancing along the other direction enters a time delay movable mirror 24. The visible light pulse advancing along the first direction causes terahertz pulse light 22a to be radiated from the terahertz pulse light source 22. The latter visible light pulse with the length of time which takes to reach a terahertz pulse detector 26 having been changed at the time delay movable mirror 24 enters the terahertz pulse detector 26 as a sampling pulse 21a.

The terahertz pulse light source 22 which may be utilized in the scanning-type imaging photometric method for measurement by irradiating the terahertz pulse light 22a at one point of a semiconductor wafer 25 is normally constituted of a semiconductor photoconductive switch device.

A semiconductor photoconductive switch device is constituted by forming an antenna (e.g., a metal alloy antenna) on a semiconductor material which achieves fast optical response when irradiated with a visible light pulse 21b emitted by the visible light pulse laser 21. The visible light pulse 21b is equivalent to the “input pulse” mentioned earlier. The terahertz pulse light 22a may be generated by irradiating visible light pulse on a compound semiconductor, instead.

A terahertz optical element constituting a photometric optical system 23a includes, for instance, an off-axis parabolic mirror which is constituted by using at least one type of mirror among the following; a mirror deposited with aluminum, a mirror deposited with gold and a mirror deposited with silver which have been treated for oxidation inhibition. The photometric optical system 23a may be constituted in combination with a silicon lens, a germanium lens, a polyethylene lens or the like as well. The polarizer is constituted of a wire grid.

The terahertz pulse detector 26 is constituted of a semiconductor photoconductive switch device that is of the same type as that constituting the terahertz pulse light source 22. An electric field is induced at this semiconductor photoconductive switch device if transmitted pulse light 25a alone is irradiated and the sampling pulse 21a is not irradiated. In such a case, no current flows through the semiconductor photoconductive switch device. However, if the sampling pulse 21a is irradiated on the semiconductor photoconductive switch device irradiated with the transmitted pulse light 25a, the sampling pulse 21a triggers generation of optically generated carriers to cause a flow of an electrical current. The level of this current corresponds to the level of the electric field intensity of the electric field induced when the transmitted pulse light 25a having been transmitted through the semiconductor wafer 25 is received. The current is amplified at a lock-in amplifier (not shown) and the current value is stored at the measurement/storage device 7 (see FIG. 3) described earlier.

The current value changes in proportion to the electric field intensity of the transmitted pulse light 25a having been transmitted through the semiconductor wafer 25. In other words, the measurement/storage device 7 measures the electric field intensity of the transmitted pulse light 25a.

Since the timing with which the sampling pulse 21a is transmitted is varied by the time delay movable mirror 24, the measurement/storage device 7 measures electric field intensity levels of the transmitted pulse light 25a by reading current values corresponding to the various time points.

In more specific terms, a sampling pulse 21a is input to the terahertz pulse detector 26 after each At interval and the electric field intensity of the transmitted pulse light 25a having been transmitted through a given pixel is read. By repeating this operation k times starting at the time point t0, the electric field intensity levels over the period of time extending from the time point t0 to the time point tk (see FIG. 4A) are read. Then, in order to obtain a two-dimensional projected image, the operation is repeated over the number of times corresponding to the required number of pixels (i×j) over the entire surface of the semiconductor wafer 25.

It is to be noted that a method in which after reading the electric field intensity levels corresponding to all the pixels at the time point t0, the electric field intensity levels at all the pixels are sequentially read by shifting the sampling pulse input time by Δt intervals may be adopted instead. The numerical value data representing the electric field intensity levels thus read out are stored at the measurement/storage device 7 (see FIG. 3).

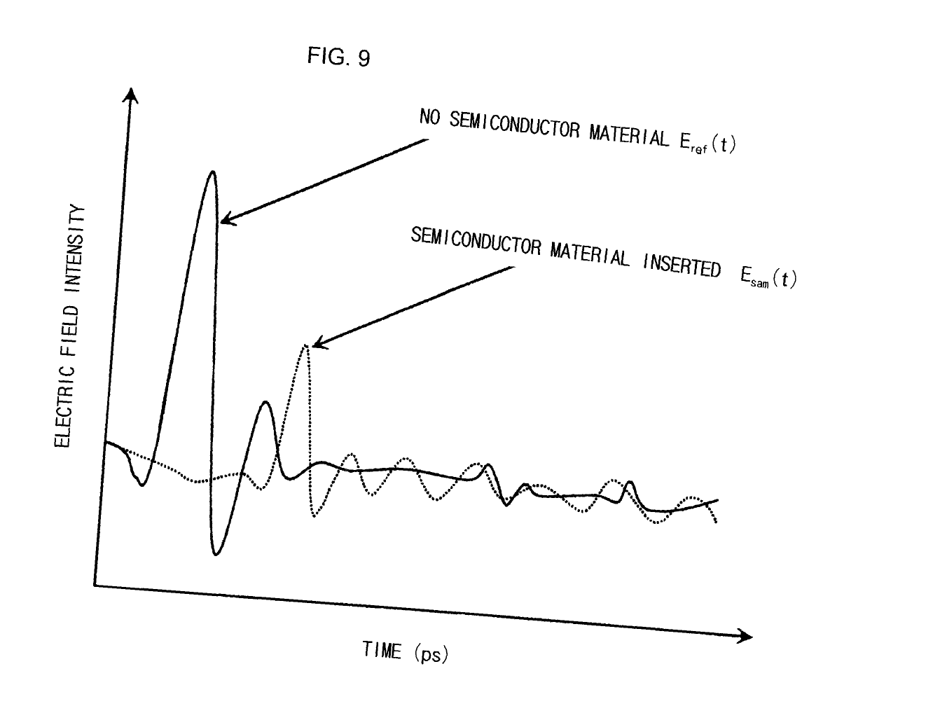

As a result, the time-series waveforms of the electric field intensity of the transmitted pulse light 25a shown in FIG. 9 are obtained. FIG. 9 presents an example of time-series waveforms of the electric field intensity extracted along the time axis with regard to a single pixel (aij). The two curves Esam(t) and Eref(t) respectively represent waveforms achieved by inserting and without inserting the semiconductor material 25 in the optical path of the photometric optical system 23a.

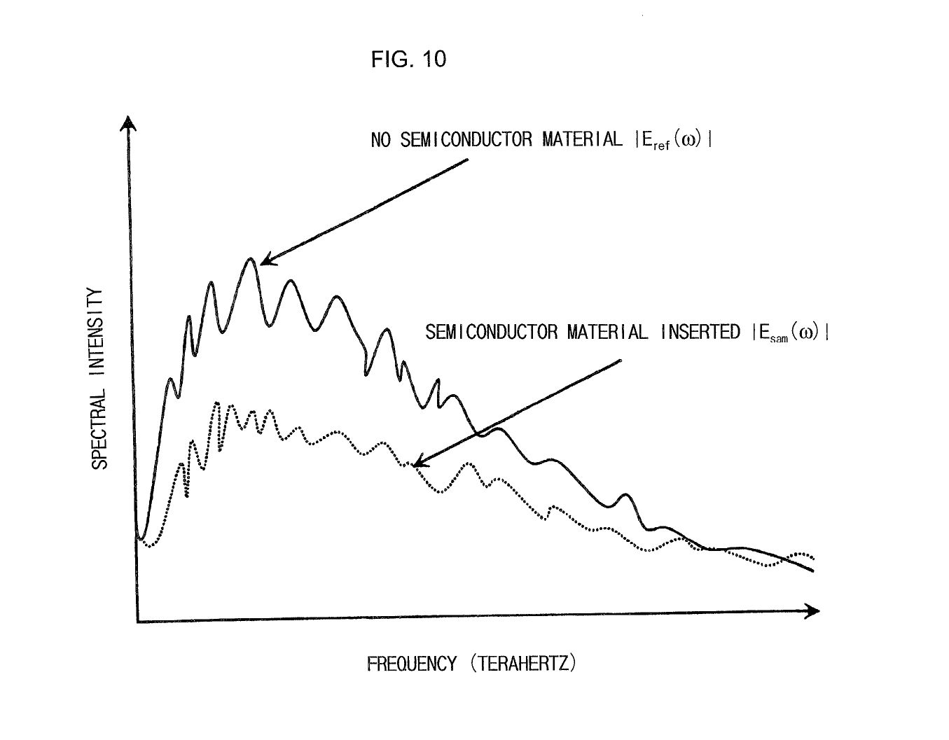

By performing a Fourier transform on the time-series waveforms at the data processing device 8 (see FIG. 3), the frequency dependency of the amplitude and the phase of the electric field intensity defined in formula (1) is ascertained. FIG. 10 presents a graph of the frequency dependency of the electric field intensity amplitude. The two curves |Esam(ω)| and |Eref(ω)| respectively correspond to time-series waveform data obtained by inserting and without inserting the semiconductor material 25 in the optical path of the photometric optical system 23a. The frequency characteristics of the electric field intensity phase, too, are obtained in a similar manner.

The measurement operation is performed by first measuring the time-series waveform Eref(t) without inserting the semiconductor material 25 in optical path of the photometric optical system 23a (see FIG. 8) to calculate the reference amplitude |Eref(ω)| and the reference phase θref. Next, with the semiconductor material 25 inserted in the optical path, the time-series waveform Esam(t) is measured and the amplitude |Esam(ω)| and the phase θsam manifested when the measurement object is inserted are calculated (see FIGS. 9 and 10).

By incorporating the values of |Eref(ω)|, |Esam(ω)|, θref and θsam thus calculated in the following formulae (14) and (15), the complex refractive index n+ik of the semiconductor material 25 can be ascertained. Formulae (14) and (15) are achieved by modifying formulae (4) and (5) explained earlier.

$$\begin{matrix}n = \frac{( {θ}_{sam } - {θ}_{ref} )}{d} \frac{c}{ω} + 1 & ( 14 ) \\ k = - \frac{c}{ω d} ln [ \frac{{( 1 + n )}^{2}}{4 n} \frac{\vert {E}_{sam} ( ω ) \vert}{\vert {E}_{ref} ( ω ) \vert} ] & ( 15 )\end{matrix}$$

By incorporating the value of the complex refractive index n+ik thus obtained in formula (10), the carrier scattering time τ is ascertained. Once the carrier scattering time τ is obtained, the carrier density N can be calculated through formula (9), and then by using formulae(11)˜(13) explained earlier, the mobility μ, the resistivity ρ and the electrical conductivity σ are calculated. A variable-density image or a color image is created and displayed by using the parameter values representing the electrical characteristics thus calculated, and, as a result, a two-dimensional projected image is obtained.

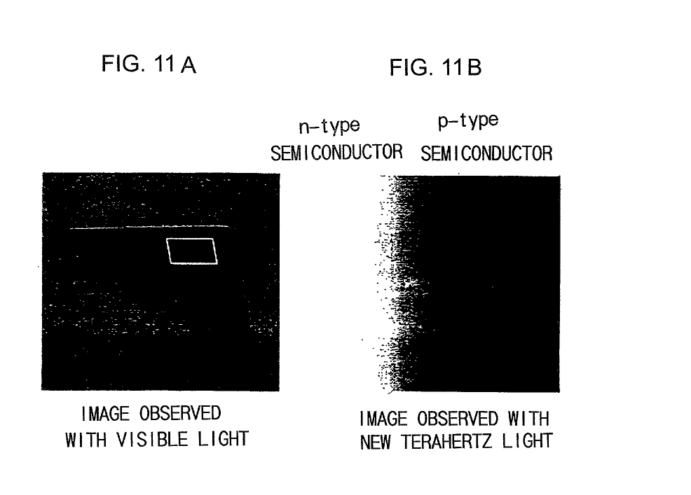

FIG. 11A is a photograph of areas of a semiconductor wafer with varying electrical characteristics, viewed with visible light, and FIG. 11B is a two-dimensional projected image of the semiconductor wafer irradiated with terahertz pulse light. FIG. 11B is a two-dimensional projected image of the resistivity ρ which is one of the electrical characteristics parameters. The difference in the contrast between the left half and the right half of the image represents a difference in the resistivity ρ and clearly indicates that the left half is an n-type semiconductor whereas the right half is a p-type semiconductor.

Through the explanation of the embodiment, the electrical characteristics evaluation apparatus according to the present invention has been proved to be an effective means to be employed in the evaluation of electrical characteristics parameters of a semiconductor material.

In the scanning-type imaging method described above, a measurement area at the semiconductor material can be selected freely by performing mechanical scanning with a condensed light flux.

While an explanation is given in reference to the embodiment above on an example in which the scanning-type imaging method is adopted, the length of time required for measurement can be greatly reduced by adopting a non-scanning-type imaging method implemented in conjunction with an image formating optical system.

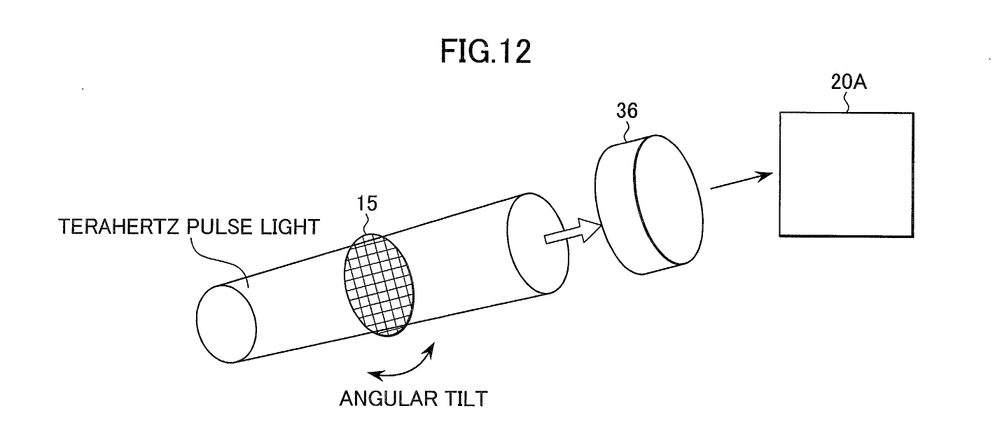

The following is an explanation of the non-scanning-type imaging method. FIG. 12 is a schematic diagram provided to illustrate the non-scanning-type imaging photometric method. As shown in the figure, the beam diameter of terahertz pulse light is increased to obtain an expanded light flux and illumination is performed at once over the entirety of the semiconductor material 15 to obtain a transmitted image in this method.

The electric field intensity distribution of the transmitted pulse light having been transmitted through the measurement object (the semiconductor material 15) within the X-Y plane is measured at once by employing an imaging camera 36 having an image forming optical system and a two-dimensional image-capturing device and a computer 20A. An advantage achieved by adopting this method is that since it is not necessary to move the measurement object by utilizing a mechanical scanning system, a transmitted image is obtained in a very short time.

By measuring the electric field intensity distribution within the X-Y plane while changing the timing Δt with which a sampling pulse is transmitted from a time delay device (not shown) to the imaging camera 36, time-series transmitted images are obtained.

By implementing a Fourier transform operation as in the scanning-type imaging photometric method at the computer 20A, a two-dimensional transmitted image (spectral image) is obtained. In addition, by performing linear conversion operation such as Radon conversion at the computer on a plurality of two-dimensional projected images obtained by changing the angle settings at which the terahertz pulse light is irradiated on the semiconductor material 15, a three-dimensional sectioned image can be obtained.

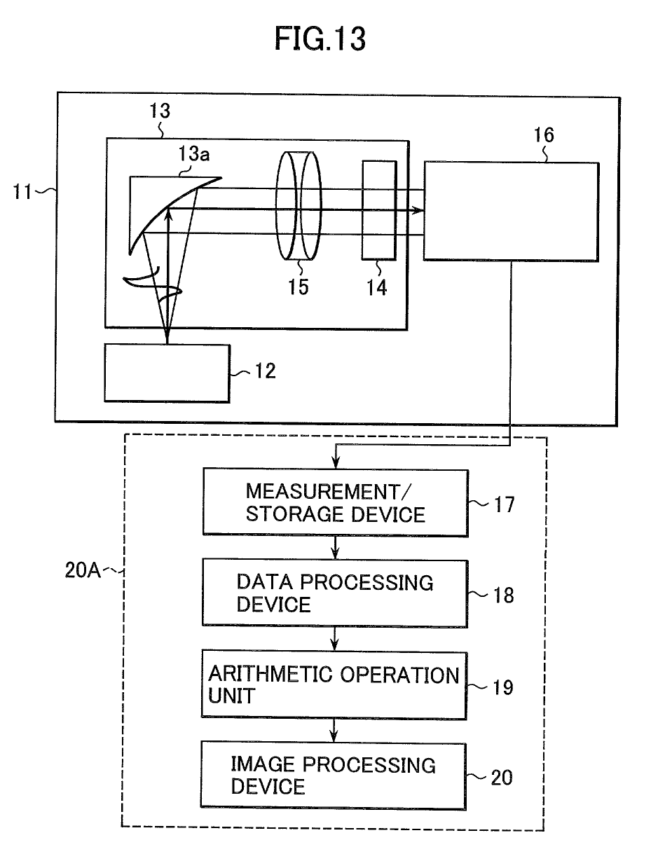

FIG. 13 is a schematic diagram of the electrical characteristics evaluation apparatus according to the present invention which adopts the non-scanning-type imaging method. At a measurement chamber 11, a terahertz pulse light source 12, a test piece chamber 13 and an image detector 16 such as a two-dimensional image-capturing device are provided. The image detector 16 in the measurement chamber 11 is connected to the computer 20A provided outside the measurement chamber 11.

The test piece chamber 13 houses therein a photometric optical system 13a which engages in a photometric operation over the entire semiconductor material 15 and an image forming optical system 14 which forms an image of transmitted pulse light having been transmitted through the semiconductor material 15. These are optical systems utilized to obtain in a batch two-dimensional projected images of the semiconductor material 15 in the terahertz frequency range.

The terahertz pulse light generated at the terahertz pulse light source 12 becomes an expanded light flux at the photometric optical system 13a, which is then irradiated at once over the entire semiconductor material 15, is transmitted through the semiconductor material 15 to form an image at the 14 and then enters the image detector 16. As explained earlier, the image detector 16 detects the transmitted image in a batch and transmits a signal which is in proportion to the electric field intensity of the transmitted pulse light to the computer 20A.

The computer 20A comprises a measurement/storage device 17, a data processing device 18, an arithmetic operation unit 19 and an image processing device 20.

The measurement/storage device 17 ascertains the electric field intensity distribution of the transmitted pulse light by taking in a transmitted image detected by the image detector 16, and also measures and stores the time-series waveform of the transmitted pulse light. The data processing device 18 converts the time-series waveform to a frequency spectrum through a Fourier transform operation performed in units of individual pixels to obtain a spectral transmittance image.

The arithmetic operation unit 19 calculates electrical parameters such as the carrier density, the mobility, the resistivity and the electrical conductivity of the semiconductor material 15 from the spectral transmittance image obtained at the data processing device 18 based upon Drude's light absorption theory.

The image processing device 20 obtains a two-dimensional projected image representing the electrical characteristics by using the numerical value data calculated at the arithmetic processing unit 19. In addition, the image processing device 20 reproduces a three-dimensional sectioned image of the inside of the semiconductor material by performing digital image processing on two-dimensional projected images on the computer.

A problem of the non-scanning-type imaging method lies in the image detector 16 detecting terahertz pulse light and, at present, there is no two-dimensional image-capturing device capable of directly receiving terahertz pulse light. However, real time terahertz imaging is enabled by adopting the electro-optics sampling method disclosed in a publication (Q.Wu et al. Appl. Phys. Lett. Vol 69, No.8, p 1026 (1996)).

In principle, a terahertz transmitted image of a semiconductor material is displayed on an imaging plate constituted of an electro-optic crystal and the terahertz pulse light image information is converted to polarization information of visible light which is then rendered to an image by taking advantage of Pockels effect through the method. Pockels effect refers to an effect whereby the refractive index of the electro-optic crystal changes depending upon the electric field intensity of the terahertz pulse light. By constituting a device capable of performing such measurement and an analysis based upon Drude's light absorption theory, it becomes possible to perform electrical characteristics evaluation of a semiconductor material in real time.

While an explanation is given above in reference to the embodiment on an example in which an analysis is performed based upon Drude's light absorption theory (see FIG. 6) to calculate the carrier density, the mobility, the resistivity and the electrical conductivity of the semiconductor material, the dielectric function theory, which takes into consideration the Lattice vibration and the presence of free carriers inside the semiconductor material may be used, instead. The adoption of the dielectric function theory is particularly effective when evaluating a compound semiconductor in which infrared-active lattice vibration occurs, i.e., a compound semiconductor that absorbs infrared electromagnetic waves.

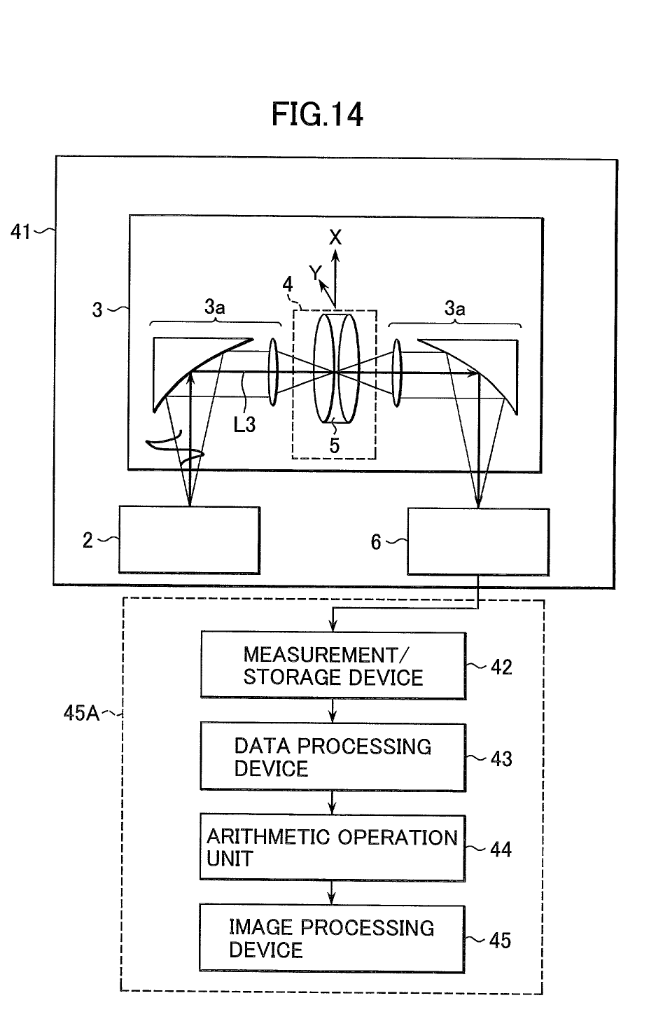

FIG. 14 is a schematic block diagram of an electrical characteristics evaluation apparatus adopting the scanning-type imaging method. A measurement chamber 41 and a measurement/storage device 42, a data processing device 43 and an image processing device 45 provided inside a computer 45A in FIG. 14 respectively assume structures identical to the measurement chamber 1, the measurement/storage device 7, the data processing device 8 and the image processing device 10 shown in FIG. 3. The explanation below mainly focuses on an arithmetic operation unit 44 which characterizes the electrical characteristics evaluation apparatus in FIG. 14.

The arithmetic operation unit 44 calculates electrical characteristics parameters such as the carrier density, the mobility, the resistivity and electrical conductivity of a semiconductor material 5 in correspondence to the frequency dependency of the spectral transmittance ascertained at the data processing device 43, based upon the dielectric function theory which is to be detailed later. Numerical value data calculated at the arithmetic operation unit 44 are rendered to two-dimensional projected images at the image processing device 45, and then the data are restructured through digital image processing performed at the computer to reproduce a three-dimensional sectioned image of the inside of the semiconductor material.

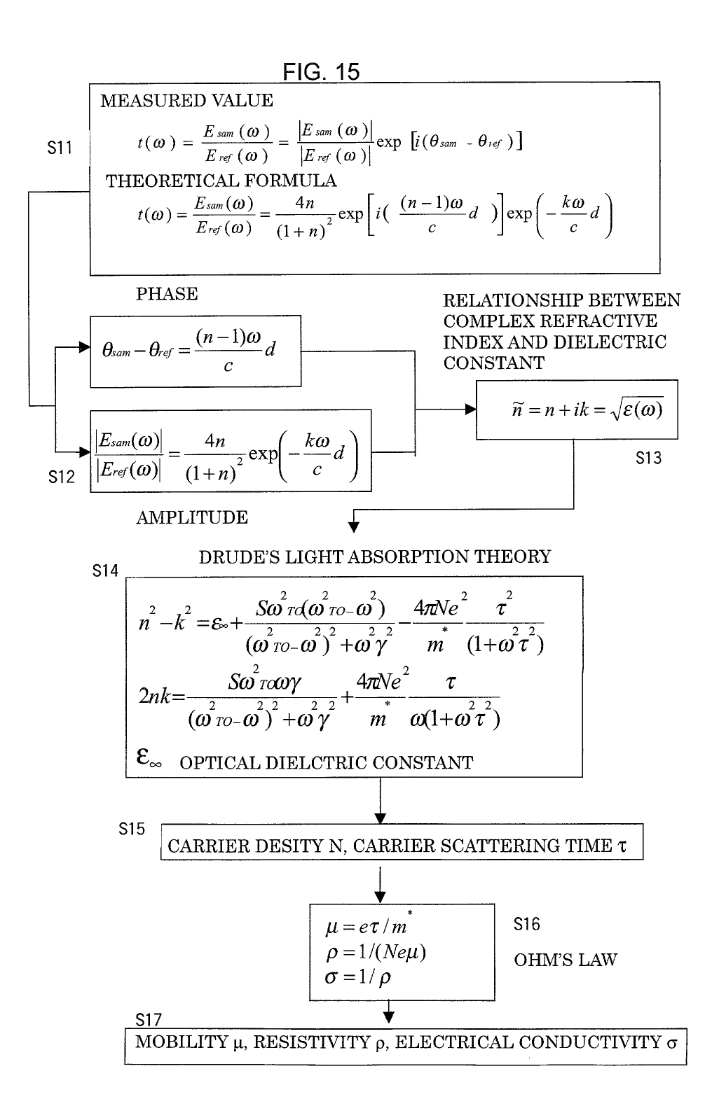

FIG. 15 is a process diagram of the method of analysis adopted to calculate the electrical material values (the carrier density, the mobility, the resistivity, electrical conductivity and the like) of the semiconductor material 5 at the electrical characteristics evaluation apparatus in FIG. 14. In the analysis procedure shown in FIG. 15, S11˜S13 and S15˜S17 are respectively identical to S1˜S3 and S5˜S7 shown in FIG. 6. S14 in FIG. 15 (the step in which the dielectric function theory is used) is mainly explained below. In order to achieve simplification, the explanation is given on the analysis performed on a single pixel.

As explained earlier, the standard relationship between the complex refractive index n+ik and the complex dielectric constantΣ(ω) obtained through S11 and S12 in FIG. 15 is expressed as in formula (6) (FIG. 15 S13).

In addition, the complex dielectric constant Σ(ω) deduced based upon the dielectric function theory when carriers are generated by adding an impurity to the semiconductor material such as a compound semiconductor material is expressed as in the following formula (16).

$$ϵ ( ω ) = {ϵ}_{∞} + \frac{S {ω}_{TO}^{2}}{{ω}_{TO}^{2} - {ω}^{2} - i ω γ} - \frac{4 π {Ne}^{2}}{{m}^{*}} \frac{1}{ω ( ω + i / τ )} \qquad ( 16 )$$

Based upon the relationship between the formulae (6) and (16), the following the formulae (17) and (18) are obtained (FIG. 15 S14). The optical dielectric constant ε∞, the frequency ω_{T0} of the optical lattice vibration, the damping factor γ, the oscillator strength S and the effective mass m* of the carriers in formulae (16)˜(18) are material constants, with their values varying depending upon the type of compound semiconductor being evaluated.

$$\begin{matrix}{n}^{2} - {k}^{2} = {ϵ}_{∞} + \frac{S {ω}_{TO}^{2} ( {ω}_{TO}^{2} - {ω}^{2} )}{{( {ω}_{TO}^{2} - {ω}^{2} )}^{2} + {ω}^{2} {γ}^{2}} - \frac{4 π {Ne}^{2}}{{m}^{*}} \frac{{τ}^{2}}{( 1 + {ω}^{2} {τ}^{2} )} & ( 17 ) \\ 2 nk = \frac{S {ω}_{TO}^{2} ω γ}{( {ω}_{TO}^{2} - {ω}^{2} ) + {ω}^{2} {γ}^{2}} + \frac{4 π {Ne}^{2}}{{m}^{*}} \frac{τ}{ω ( 1 + {ω}^{2} {τ}^{2} )} & ( 18 )\end{matrix}$$

Since the complex refractive index n+ik of the semiconductor material can be actually measured by the measurement/storage device 42 and the data processing device 43 in FIG. 14 (FIG. 15 S12), unknowns in formulae (17) and (18) are the carrier density N and the carrier scattering time τ.

The relationship between the carrier scattering time τ and the complex refractive index n+ik is analytically expressed as in the following formula (19) by solving formulae (17) and (18) above as simultaneous equations.

$$τ = \frac{1}{ω} ( \frac{( {ϵ}_{∞} - {n}^{2} + {k}^{2} ) \{ {( {ω}_{TO}^{2} - {ω}^{2} )}^{2} + {ω}^{2} {γ}^{2} \} + S {ω}_{TO}^{2} ( {ω}_{TO}^{2} - {ω}^{2} )}{2 nk \{ {( {ω}_{TO}^{2} - {ω}^{2} )}^{2} + {ω}^{2} {γ}^{2} \} - S {ω}_{TO}^{2} ω γ} ) \qquad ( 19 )$$

Thus, the carrier scattering time τ is ascertained through formula (19) and based upon the relationship expressed in formula (18), the carrier density N is obtained (FIG. 15 S15).

Then, by incorporating the values of the carrier density N and the carrier scattering time τ thus obtained into the Ohm's Law (formulae (11)˜(13)) (FIG. 15 S16), the mobility μ, the resistivity ρ and the electrical conductivity σ are calculated (S17).

The numerical value data calculated through the procedure described above are output from the arithmetic operation unit 44 to the image processing device 45. The calculated numerical value data are rendered to a variable-density image or a color image at the image processing device 45, to obtain a two-dimensional projected image representing the electrical characteristics parameters (carrier density N, the mobility μ, the resistivity ρ and electrical conductivity σ) of the semiconductor.

A plurality of two-dimensional projected images are obtained at the image processing device 45 by varying the angle setting at which the semiconductor material is irradiated with the terahertz pulse light, and by performing a linear conversion operation such as Radon conversion on the two-dimensional projected images, a three-dimensional sectioned image representing the electrical characteristics parameters (the carrier density N, the mobility μ, the resistivity ρ and electrical conductivity σ) of the semiconductor material is obtained.

It is to be noted that when determining the two unknowns (the carrier density N and the carrier scattering time τ) in formulae (17) and (18), an optimization operation such as a standard nonlinear method of least squares may be performed by using the unknowns (N and τ) as optimization parameters.

Instead of the scanning-type imaging method (see FIG. 14), the non-scanning-type imaging method may be adopted by employing an image forming optical system. When the nonscanning-type imaging method is adopted, too, the dielectric function theory can be used to calculate the carrier density, the mobility, the resistivity and the electrical conductivity of a semiconductor material, e.g., a compound semiconductor material.

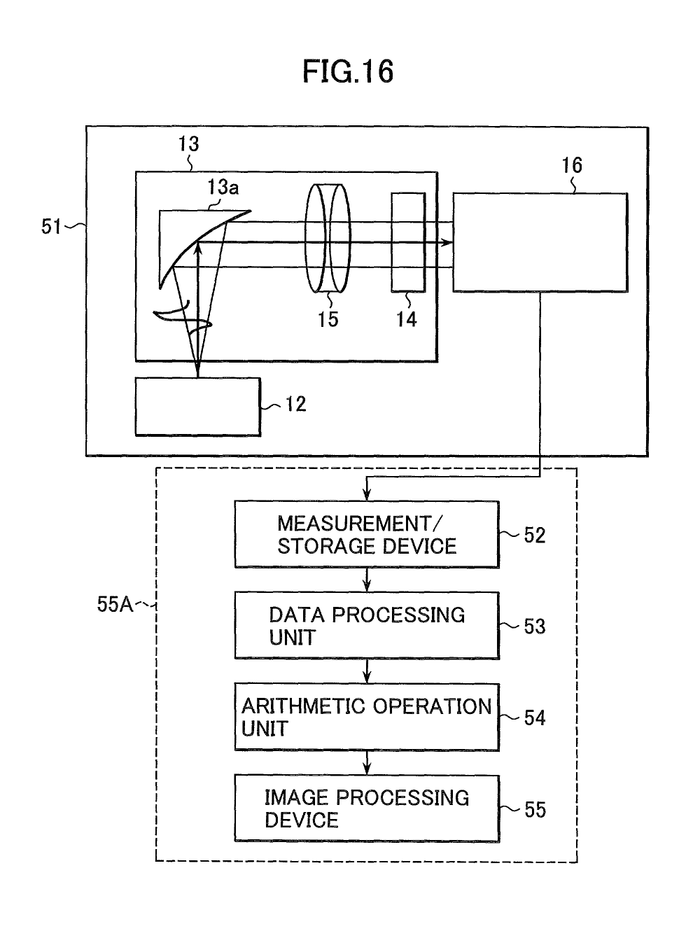

FIG. 16 is a schematic block diagram of an electrical characteristics evaluation apparatus adopting the non-scanning-type imaging method. A measurement chamber 51 and a measurement/storage device 52, a data processing device 53 and an image processing device 55 provided inside a computer 55A shown in FIG. 16 respectively assume structures identical to the measurement chamber 11, the measurement/storage device 17, the data processing device 18 and the image processing device 20 shown in FIG. 13. The explanation below mainly focuses on an arithmetic operation unit 54 which characterizes the electrical characteristics evaluation apparatus in FIG. 16.

The arithmetic operation unit 54 calculates electrical characteristics parameters such as the carrier density, the mobility, the resistivity and the electrical conductivity of a semiconductor material 15 in correspondence to a spectral transmittance image (spectral image) obtained at the data processing device 53 based upon the dielectric function theory explained above. The numerical value data calculated at the arithmetic operation unit 54 are rendered to a two-dimensional projected image at the image processing device 55, and then the data are restructured through digital image processing performed at the computer to reproduce a three-dimensional sectioned image of the inside of the semiconductor material.

By adopting this nonscanning-type imaging method, in which the entirety of the semiconductor material 15 is irradiated at once with terahertz pulse light and a transmitted image representing the electric field intensity distribution of the transmitted pulse light within the X-Y plane is measured in a batch, the length of time required for the measurement is greatly reduced.

Specific examples of apparatuses that measure and evaluate the electrical characteristics parameters of a semiconductor material by obtaining the spectral transmittance or a spectral transmittance image in correspondence to terahertz pulse light (transmitted pulse light or a transmitted image) having been transmitted through the semiconductor material have been explained in reference to the embodiments above. The present invention may also be adopted in an apparatus that measures and evaluates the electrical characteristics parameters of a semiconductor material by obtaining the spectral reflectance or a spectral reflectance image in correspondence to terahertz pulse light (reflected pulse light or a reflected image) having been reflected by the semiconductor material.

By adopting the electrical characteristics evaluation apparatus and the electrical characteristics evaluation method according to the present invention, light in the terahertz frequency range which is sensitive to the electrical characteristics of a semiconductor material is used and the carrier density, the mobility, the resistivity and the electrical conductivity representing the electrical characteristics of the semiconductor material are calculated based upon information on the terahertz pulse light having been transmitted or reflected. As a result, simple and real time measurement and evaluation are enabled without inducing any destruction of or contact with the semiconductor material.

By using Drude's analysis method or the dielectric function theory to calculate the electrical characteristics values of the semiconductor material, the coefficient of light absorption can be easily calculated in correspondence to the complex refractive index of the semiconductor material.

What is claimed is:

1. A semiconductor electrical characteristics evaluation apparatus comprising;
a terahertz pulse light source that irradiates terahertz pulse light onto a semiconductor material;
a light detector that detects transmitted pulse light having been transmitted through the semiconductor material or reflected pulse light having been reflected by the semiconductor material;
a measurement device that obtains a spectral transmittance or a spectral reflectance based upon a time-series waveform of the electric field intensity of the transmitted pulse light or the reflected pulse light detected by said light detector; and
an arithmetic operation unit that calculates an electrical characteristics parameter of the semiconductor material in conformance to the spectral transmittance or the spectral reflectance.

2. A semiconductor electrical characteristics evaluation apparatus according to claim 1, wherein;
said arithmetic operation unit calculates an electrical characteristics parameter by executing an analysis based upon Drude's light absorption theory.

3. A semiconductor electrical characteristics evaluation apparatus according to claim 1, wherein;
said arithmetic operation unit calculates an electrical characteristics parameter by executing an analysis based upon dielectric function theory.

4. A semiconductor electrical characteristics evaluation apparatus according to claim 1, further comprising;
an image processing device that renders the electrical characteristic parameter to a two-dimensional image as a spatial distribution.

5. A semiconductor electrical characteristics evaluation apparatus according to claim 2, further comprising;
an image processing device that renders the electrical characteristic parameter to a two-dimensional image as a spatial distribution.

6. A semiconductor electrical characteristics evaluation apparatus according to claim 3, further comprising;
an image processing device that renders an electrical characteristic parameter to a two-dimensional image as a spatial distribution.

7. A semiconductor electrical characteristics evaluation apparatus according to claim 1, further comprising;
a condenser optical system that condenses the terahertz pulse light and guides a condensed light flux to the semiconductor material; and
a mechanical scanning system that causes the condensed light flux and the semiconductor material to move relative to each other so that the light flux can be scanned on a surface of the semiconductor material.

8. A semiconductor electrical characteristics evaluation apparatus according to claim 1, further comprising;
an expansion optical system that expands the diameter of the terahertz pulse light and guides and expanded light flux to an entire surface of the semiconductor material at once, wherein;
said light detector is constituted of a two-dimensional light detector that two-dimensionally detects transmitted pulse light or reflected pulse light having been transmitted through or having been reflected by the semiconductor material irradiated with the expanded light flux.

9. A semiconductor electrical characteristics evaluation apparatus according to claim 7, further comprising;
a tilt mechanism that tilts the condensed light flux and the semiconductor material relative to each other; and
a computer graphic device that synthesizes a three-dimensional sectioned image from a plurality of two-dimensional images obtained at varying tilt angles.

10. A semiconductor electrical characteristics evaluation apparatus according to claim 8, further comprising;
a tilt mechanism that tilts the expanded light flux and the semiconductor material relative to each other; and
a computer graphic device that synthesizes a three-dimensional sectioned image from a plurality of two-dimensional images obtained at varying tilt angles.

11. A semiconductor electrical characteristics evaluation apparatus according to claim 1, wherein;
said electrical characteristics parameter is one of; carrier density, mobility, resistivity and electrical conductivity, or a combination thereof.

12. A semiconductor electrical characteristics evaluation method, comprising;
a step in which terahertz pulse light is condensed and a condensed light flux is irradiated on a semiconductor material;
a step in which the condensed light flux and the semiconductor material are caused to move relative to each other so that the light flux can be scanned on a surface of the semiconductor material and transmitted pulse light or reflected pulse light having been transmitted through or having been reflected from individual points on the semiconductor material is sequentially detected;
a step in which a spectral transmittance or a spectral reflectance is calculated by using a time-series waveform of the electric field intensity of the transmitted pulse light or the reflected pulse light that has been detected; and
a step in which an electrical characteristics parameter of the semiconductor material is calculated based upon the spectral transmittance or the spectral reflectance thus calculated.

13. A semiconductor electrical characteristics evaluation method, comprising;
a step in which a diameter of terahertz pulse light is expanded and an expanded light flux is irradiated over an entire surface of a semiconductor material at once;
a step in which transmitted pulse light or reflected pulse light having been transmitted through or having been reflected by the semiconductor material irradiated with the expanded light flux is detected at once;
a step in which a spectral transmittance or a spectral reflectance is calculated by using a time-series waveform of electric field intensity of the transmitted pulse light or the reflected pulse light that has been detected; and
a step in which an electrical characteristics parameter of the semiconductor material is calculated based upon the spectral transmittance or the spectral reflectance thus calculated.

14. A semiconductor electrical characteristics evaluation method according to claim 12, wherein;
the spectral transmittance or the spectral reflectance is calculated based upon a time-series waveform of the electric field intensity obtained by inserting the semiconductor material in an optical path for detection of the transmitted pulse light or the reflected pulse light and a time-series waveform of the electric field intensity obtained without inserting the semiconductor material in the optical path.

15. A semiconductor electrical characteristics evaluation method according to claim 13, wherein;
the spectral transmittance or the spectral reflectance is calculated based upon a time-series waveform of the electric field intensity obtained by inserting the semiconductor material in an optical path for detection of the transmitted pulse light or the reflected pulse light and a time-series waveform of the electric field intensity obtained without inserting the semiconductor material in the optical path.

16. A semiconductor electrical characteristics evaluation method according to claim 12, wherein;
the spectral transmittance or the spectral reflectance is calculated based upon Drude's light absorption theory or dielectric function theory.

17. A semiconductor electrical characteristics evaluation method according to claim 13, wherein;
the spectral transmittance or the spectral reflectance is calculated based upon Drude's light absorption theory or dielectric function theory.

18. A semiconductor electrical characteristics evaluation method according to claim 12, wherein;
said electrical characteristics parameter is one of; carrier density, mobility, resistivity and electrical conductivity, or a combination thereof.

19. A semiconductor electrical characteristics evaluation method according to claim 13, wherein;
said electrical characteristics parameter is one of; carrier density, mobility, resistivity and electrical conductivity, or a combination thereof.
